(19) United States
(12) Patent Application Publication
(10) Pub. No.: US 2024/0365644 A1
(43) Pub. Date: Oct. 31, 2024

(54) DISPLAY DEVICE

(71) Applicant: Samsung Display Co., LTD., Yongin-si, Gyeonggi-do (KR)

(72) Inventors: Hyun Seung SEO, Yongin-si (KR); Ji Hyun KO, Yongin-si (KR); Jinsu NAM, Yongin-si (KR); Yong Kyu KANG, Yongin-si (KR); JUN HO LEE, Yongin-si (KR)

(73) Assignee: Samsung Display Co., LTD., Yongin-si, Gyeonggi-do (KR)

(21) Appl. No.: 18/419,237

(22) Filed: Jan. 22, 2024

(30) Foreign Application Priority Data
Apr. 27, 2023 (KR) 10-2023-0055430

(51) Int. Cl. H10K 59/80

(52) U.S. Cl. CPC H10K 59/873

(57) ABSTRACT

A display device according to an embodiment includes a display panel and a cover window disposed at a front of the display panel and including a front part and a side part that surrounds the front part and is at least partially curved, the cover window includes the front part and a second part including at least a portion of the side part, and the first part and the second part are directly bonded, and the first part has a greater hardness than the second part.

### CROSS-REFERENCE TO RELATED APPLICATION(S)

This application claims priority to and benefits of Korean Patent Application No. 10-2023-0055430 under 35 U.S.C. § 119 filed at the Korean Intellectual Property Office on Apr. 27, 2023, the entire contents of which are incorporated herein by reference.

### BACKGROUND

### 1. Technical Field

The disclosure relates to a display device, and, to a display device including a high-hardness cover window.

### 2. Description of the Related Art

Display devices are used to display images in various electronic devices such as mobile phones, tablets, wearable devices, laptop computers, televisions, and monitors.

Such a display device may include a display panel displaying an image and a cover window protecting the display panel.

A wearable device requires a cover window made of a material of high hardness, and a watch or smart watch, which is a representative wearable device, is formed in more diverse designs.

Accordingly, a cover window that implements various form factors while using high-hardness materials is required.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a cover window of high hardness in a wearable device. embodiments also provide a cover window that implements various form factors while using high-hardness materials.

A display device according to an embodiment may include a display panel and a cover window disposed on a front side of the display panel, and a front part and a side part that is at least partially curved and surrounds the front part.

The cover window may include a first part comprising the front part and a second part comprising at least a part of the side part, and the first part and the second part are directly bonded, and the hardness of the first part is greater than that of the second part.

A thickness of a bonding interface between the first part and the second part of the cover window may be less than or equal to about 100 nm.

The first part and the second part may be directly bonded after bonding surfaces of the first part and the second part are activated by plasma.

The side part of the cover window may include a first side part protruding from the front part and having at least a part of a substantially curved surface, and a second side part extending downward from the first side part and having at least a part of a substantially curved surface.

The first part of the cover window may include the front part and the first side part, and the second part of the cover window may include the second side part.

The first part of the cover window may include sapphire.

A depth from an edge of a side part of the cover window to an inner surface of the front surface may be about 3 mm or more.

The side part of the cover window may further include a third side part extending downward from the second side part, at least a portion of which is a substantially curved surface. The cover window may further include a third part extending from the second part.

The first part of the cover window may include the front part and the first side part, the second part of the cover window may include the second side part, and the second part of the cover window may include the third side part. The cover window may include a side part, and the first part may have greater hardness than the third part.

The third side part of the cover window may include a black material.

A bonding interface between the second part and the third part may have a thickness of about 100 nm or less.

The second part and the third part may be directly bonded after bonding surfaces of the second part and the third part are activated by plasma.

The first part of the cover window may include sapphire.

A display device according to an embodiment may include a display panel and a cover window disposed on a front side of the display panel, the cover window including a flat front part and at least a partially curved side part surrounding the flat front part, and the flat front part and the side part are directly bonded, and the flat front part has a greater hardness than the side part.

The side part may further include a first side part protruding and extending from the flat front part and a second side part extending downward from the first side part.

The second side part may include a black material.

The flat front part may include sapphire.

A thickness of a bonding interface between the flat front part and the side part may be about 100 nm or less.

The flat front part and the side part may be directly bonded after a bonding surface is activated by plasma.

The first side part and the second side part may be directly bonded, and a thickness of the bonding interface may be about 100 nm or less.

According to embodiments, a display device including a high-hardness cover window may be provided.

It is possible to provide a cover window that implements various form factors while using a high-hardness material.

### BRIEF DESCRIPTION OF THE DRAWINGS

The above and other aspects and features of the disclosure will become more apparent by describing in detail embodiments thereof with reference to the attached drawings, in which:

FIG. 1 is a schematic perspective view of a display device according to an embodiment.

FIG. 2 is a schematic cross-sectional view of the display device taken along line A-A′ in FIG. 1.

FIG. 3 is a schematic cross-sectional view of a cover window according to an embodiment.

FIG. 4 is a drawing illustrating a manufacturing process of a cover window according to an embodiment.

FIG. 5 is a schematic view illustrating a direct bonding process according to an embodiment.

FIG. 6 is a picture of a cover window according to an embodiment.

FIG. 7 is a cross-sectional photograph of the cover window taken along line B-B′ in FIG. 6.

FIG. 8 to FIG. 10 are schematic cross-sectional views of a cover window according to an embodiment.

FIG. 11 is a schematic cross-sectional view of a display panel according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

This disclosure may be embodied in many different forms and is not limited to the embodiments set forth herein.

In order to clearly describe the disclosure, parts irrelevant to the description may be omitted, and the same reference numerals are assigned to the same or similar constituent elements throughout the specification.

Additionally, the sizes and thicknesses of each component shown in the drawings are depicted arbitrarily for convenience of description, and therefore, the disclosure is not necessarily limited to what is shown.

In the drawings, the thickness is shown enlarged to clearly express the various layers and regions.

In the drawings, for convenience of explanation, the thicknesses of some layers and regions are exaggerated.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

In addition, when a part such as a layer, film, region, or plate is said to be “above” or “on” another part, this includes not only the case where it is “directly on” the other part, but also the case where another part or parts is/are in the middle.

Conversely, when a part is said to be “directly on” another part, it means that there is no other part in between.

In addition, being “above” or “on” a reference part means being positioned above or below the reference part, and does not necessarily mean being positioned “above” or “on” in the opposite direction of gravity.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Also, throughout the specification, when reference is made to “planar image,” it means when the target part is viewed from above, and when reference is made to “cross-sectional image,” it means when the cross-section of the target part cut vertically is viewed from the side.

In the drawings, the symbols “x”, “y,” and “z” are used to indicate directions, where “x” is a first direction, “y” is a second direction perpendicular to the first direction, and “z” is a third direction perpendicular to the first and second directions.

The first direction (x), the second direction (y), and the third direction (z) may correspond to a horizontal direction, a vertical direction, and a thickness direction, respectively, of the display device.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

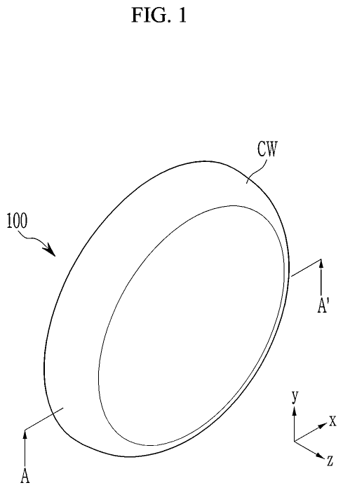

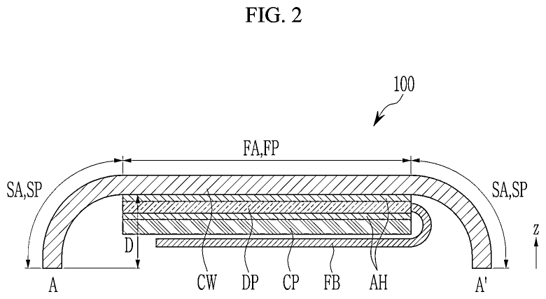

FIG. 1 is a schematic perspective view of a display device according to an embodiment, and FIG. 2 is a schematic cross-sectional view of the display device taken along line A-A′ in FIG. 1.

Referring to FIG. 1 and FIG. 2, the display device 100 may include a cover window CW, a display panel DP positioned on the backside of the cover window CW, a cover panel CP positioned on the backside of the display panel DP, and a flexible printed circuit board FB connected to the display panel DP.

The display device 100 may be used to display images on electronic devices such as watches, smart watches, mobile devices, and wearable devices.

The display device 100 may include a front region FA and a side region SA as a whole.

The side region SA may extend from the front region FA and may surround the front region FA.

The front region FA may be a flat surface, but at least a portion thereof may be a curved surface.

The side region SA may have a ring-like shape or may have a curved surface.

The entire front region FA of the display device 100 may constitute a screen.

The side region SA may not constitute a screen, but at least a part thereof may constitute a screen.

The screen may correspond to the display area of the display device 100 or the display panel DP.

When viewing the display device 100 from the front, a circular screen provided by the front region FA or at least a portion of the front region FA and the side region SA may be recognized.

In the display device 100, the cover window CW, the display panel DP, and the cover panel CP may be attached to each other.

An adhesive film such as an optically clear adhesive (OCA) can be used for the lamination of the cover window CW and display panel DP, and an adhesive layer (AH) formed by such adhesive may be positioned between the cover window CW and display panel DP.

An adhesive film such as a pressure-sensitive adhesive (PSA) may be used to attach the cover panel CP and the display panel DP, and an adhesive layer AH formed of such an adhesive is provided between the cover panel CP and the display panel DP.

The cover window CW may protect the display panel DP from the external environment or an impact.

The cover window CW may serve as a support for maintaining the display panel DP in a given state.

At least a region of the cover window CW corresponding to the screen may be optically transparent.

The cover window CW may be formed of a transparent and hard material such as glass or plastic so that an image displayed by the display panel DP may be transmitted therethrough.

In an embodiment, the cover window CW may be formed of a high-hardness material such as sapphire.

Sapphire can provide superior optical and surface hardness properties compared to other materials.

In some cases, the sapphire material may have a hardness of about 9 on the Mohs scale.

Due to the excellent hardness of sapphire, the surface strength and scratch resistance of the cover window CW including sapphire can be improved.

The cover window CW may form the overall appearance of the display device 100.

In an electronic device to which the display device 100 is applied, the cover window CW may be exposed to the outside, and the display panel DP, the cover panel CP, and the flexible printed circuit board FB are connected to the cover window CW. It may be positioned within a housing defined by a set cover.

The cover window CW may define the front region FA and the side region SA of the display device 100.

The cover window CW may include a front part FP and a side part SP corresponding to the front region FA and the side region SA of the display device 100, respectively.

The side part SP may protrude from the front part FP.

The side part SP may extend from the front part FP and may surround the front part FP.

The side part SP may include a portion curved from the front part FP to a preset radius of curvature.

The cover window CW may have a shape in which the front part FP is concave from the side part SP.

The depth D of the concave portion—for example, the depth D from the edge of the side part SP to the inner surface of the front part FP—may be about 3 mm or more, or about 4 mm or more.

For example, the depth D of the concave portion may be about 3.5 mm.

Depending on an embodiment, the cover window CW may be composed of one or more parts and may include one or more materials.

For example, the cover window CW may be divided into two parts, a front part FP and a side part SP, and may be formed of different materials.

The side part SP may be further divided into one or more parts.

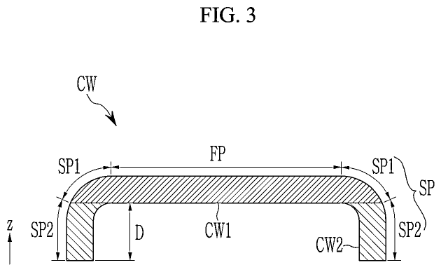

For example, the cover window CW extends in the horizontal direction from the front part FP and the front part FP, and is among the first part including the curved first side part (SP1; refer to FIG. 3) and the side part SP. It may be divided into the remaining part, the second side part (SP2; refer to FIG. 3).

Each part constituting the cover window CW may be formed of different materials.

A portion including the front part FP of the cover window CW may be formed of a material having higher hardness than other portions.

The display panel DP may be a light emitting display panel including light emitting devices such as a light emitting diode.

The display panel DP may be a touch screen panel including a touch sensing function.

At least a portion of the display panel DP may be flexible.

The display panel DP may include a display area corresponding to a screen on which an image is displayed and a non-display area on which an image is not displayed.

Pixels are arranged or disposed in the display area, and an image can be displayed by a combination of the pixels.

The non-display area may be positioned at an edge of the display panel DP and may be positioned around the display area.

The non-display area is a region where circuits and/or wires for generating and/or transmitting various signals applied to the display area are disposed.

A pad unit including pads for receiving signals from the outside of the display panel DP or outputting signals to the outside of the display panel DP may be positioned in the non-display area. A flexible printed circuit board FB may be connected or bonded to the pad part.

The cover panel CP may protect the display panel DP from the rear environment of the display panel DP (for example, impact, electromagnetic waves, and noise).

The cover panel CP can diffuse heat generated from the display panel DP and heat generated from a processor, battery, memory, etc., which may be positioned on the rear surface of the display panel DP in an electronic device to prevent transmission.

The flexible printed circuit board FB may be connected to the pad part of the display panel DP to transmit signals for driving the display panel DP to the display panel DP.

A driving integrated circuit chip (not shown) that generates and/or processes signals for driving the display panel DP may be mounted on the flexible printed circuit board FB.

At least a portion of the flexible printed circuit board FB may be bent to be positioned on the rear surface of the cover panel CP.

Since the cover window CW according to an embodiment has a sufficient depth D, the display panel DP and the cover panel CP may be positioned within a space defined by the cover window CW.

The display panel DP and the cover panel CP may be completely accommodated in the concave portion of the cover window CW without protruding from the side part SP of the cover window CW.

FIG. 3 is a schematic cross-sectional view of a cover window according to an embodiment.

Referring to FIG. 3, the cover window CW may include a front part FP and a side part SP protruding from the front part FP.

The side part SP may include a portion curved from the front part FP to a preset radius of curvature.

The side part SP may extend from the front part FP and may surround the front part FP.

The cover window CW may have a shape in which the front part FP is concave from the side part SP.

The depth D of the concave portion—for example, the depth D from the edge of the side part SP to the inner surface of the front surface FP—may be about 3 mm or more, or about 4 mm or more.

For example, the depth D of the concave portion may be about 3.5 mm.

The cover window CW according to an embodiment may include a first part CW1 and a second part CW2.

The first part CW1 of the cover window may include a front part FP and a portion of the side part SP, which is a curved surface extending from the front part FP.

For example, the first part CW1 of the cover window may include a flat front part FP and a curved first side part SP1 extending in parallel in a horizontal direction from the front part FP.

A lower surface of the front part FP and a lower surface of the first side part SP1 may be positioned on the same plane.

The first part CW1 of the cover window may be formed of a material that is transparent and has high hardness.

For example, it may include sapphire.

The second part CW2 of the cover window may include a second side part SP2 extending downward from the first side part SP1.

The second part CW2 of the cover window may have a ring-like shape and may include a curved surface.

The second part CW2 of the cover window may be formed of a material that is transparent and has high hardness.

For example, the second part CW2 of the cover window may be formed of tempered glass or ceramic.

The first part CW1 of the cover window and the second part CW2 of the cover window may be formed of different materials.

The second part CW2 of the cover window may be formed of a material having a lower hardness than the first part CW1 of the cover window.

Depending on the embodiment, the first part CW1 of the cover window and the second part CW2 of the cover window may be formed of the same material or a similar material.

In an embodiment, the first part CW1 of the cover window may be sapphire, and the second part CW2 of the cover window may be tempered glass or ceramic glass.

Sapphire is a material with excellent hardness and is good for use in wearable materials, but it has a disadvantage in that it is difficult to mold.

Therefore, it may be difficult to use the cover window CW having a concave portion with sufficient depth D.

However, since an embodiment molds the front part FP and part of the side part SP1 using sapphire of high hardness material and uses a material with good workability such as tempered glass or ceramic, the processability is improved while using the material of high hardness. Thus, an excellent cover window can be produced.

The first part CW1 of the cover window and the second part CW2 of the cover window may be connected or coupled by direct bonding.

For example, a separate adhesive layer is not positioned between the first part CW1 of the cover window and the second part CW2 of the cover window, and the lower surface of the first side part SP1 constituting the first part CW1 of the cover window, and the upper surface of the second side part SP2 constituting the second part CW2 of the cover window may be in direct contact.

Since the first part CW1 of the cover window and the second part CW2 of the cover window are connected or coupled by direct bonding, it may be difficult to visually recognize the boundary portion.

For example, the thickness of the bonding interface formed by direct bonding is about 100 nm or less, and may be formed at a level of several nm to several tens of nm depending on the embodiment.

Since the cover window according to an embodiment is divided into two parts and processed, a front part having sufficient hardness and a side part for realizing various form factors can be molded. Accordingly, a form factor having sufficient depth while using a material of high hardness can be formed. A cover window that implements such may be provided.

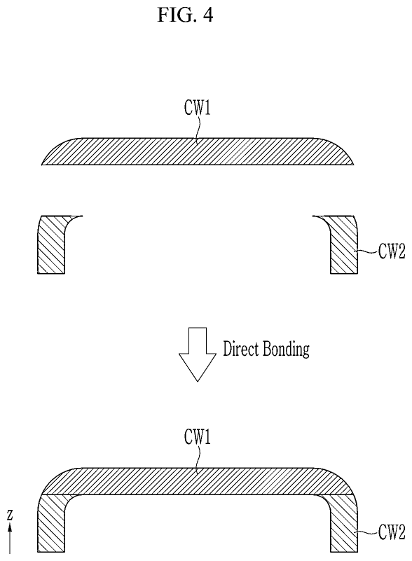

Hereinafter, a manufacturing process of a cover window according to an embodiment will be described with reference to FIG. 4.

Referring to FIG. 4, a first part CW1 of the cover window and a second part CW2 of the cover window are provided.

The first part CW1 of the cover window may include a front part corresponding to the front region of the display device and a portion of the side part extending from the front part.

An upper surface of the first part CW1 of the cover window may include a flat portion corresponding to the front part and a curved portion protruding from the front part.

A lower surface of the first part CW1 of the cover window may form one flat surface.

The first part CW1 of the cover window may be formed of a transparent material, and a material having high hardness may be used.

For example, sapphire, having excellent optical properties and excellent surface hardness, can be used.

The second part CW2 of the cover window may include a side part corresponding to the side region of the display device.

The second part CW2 of the cover window may be positioned below the first part CW1 of the cover window.

The second part CW2 of the cover window may have a ring shape surrounding the boundary of the first part CW1 of the cover window.

The second part CW2 of the cover window may be formed of a transparent material, has high hardness, and may be processed using various materials required for a form factor.

For example, tempered glass, ceramic glass, and the like may be used.

The first part CW1 of the cover window and the second part CW2 of the cover window may be connected or coupled by direct bonding.

A lower surface of the first part CW1 of the cover window may be disposed to face an upper surface of the second part CW2 of the cover window.

At the boundary defining the first part CW1 of the cover window, the first part CW1 and the second part CW2 of the cover window may be attached by direct bonding.

The second part CW2 of the cover window may be bonded in a ring shape surrounding and exposing a front part of the first part CW1 below the first part CW1 of the cover window.

A separate material is not required for bonding between the first part CW1 and the second part CW2 of the cover window, and the thickness of the bonding interface is less than about 100 nm and is not visible to the naked eye.

Depending on the embodiment, the thickness of the bonding interface may be formed to a level of several nm to several tens of nm.

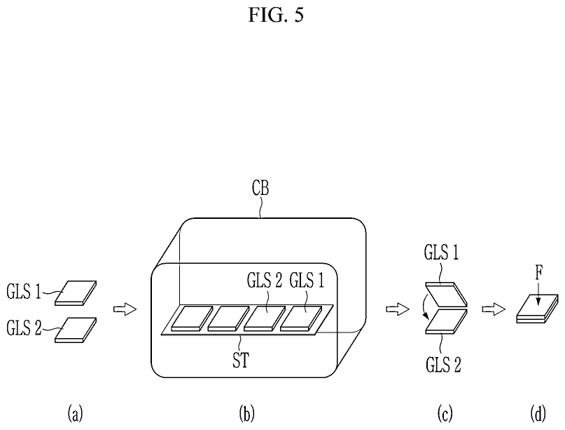

FIG. 5 is a schematic view illustrating a direct bonding process according to an embodiment.

Referring to FIG. 5, direct bonding will be briefly described.

FIG. 5 (a) shows a step of preparing an upper substrate GLS1 and a lower substrate GLS2, and FIG. 5 (b) shows a surface treatment step of the substrates (GLS1 and GLS2) performed inside the chamber CB. FIG. 5 (c) shows a preliminary bonding step of the surface-treated substrates (GLS1 and GLS2), and FIG. 5 (d) shows a pressing step of pressing the pre-bonded substrates (GLS1 and GLS2).

By way of example, FIG. 5 (a) is a step of preparing an upper substrate GLS1 and a lower substrate GLS2 for bonding, and the upper and lower substrates may be of different types or may be of the same type.

For example, the upper substrate may be formed of high-hardness sapphire, and the lower substrate may be formed of tempered glass or ceramic glass that is advantageous in molding.

The upper and lower substrates may be pre-formed according to a desired form factor after bonding.

For example, as shown in FIG. 4, the upper substrate GLS1 is the first part CW1 of the cover window according to an embodiment, and the lower substrate GLS2 is the second part CW2 of the cover window according to an embodiment. It may be part CW2.

Here, the first part CW1 is molded to include the front part of the cover window, and the second part CW2 may include the side part of the cover window and is formed in an annular shape surrounding the boundary of the first part CW1.

FIG. 5 (b) shows a surface treatment step of substrates performed inside the chamber CB, and the upper substrate GLS1 and the lower substrate GLS2 may be positioned on a stage ST inside the chamber CB.

The chamber CB is a plasma chamber CB in which plasma is formed by injecting oxygen, nitrogen, argon gas, etc. in a vacuum state.

The upper and lower substrates (GLS1 and GLS2) positioned inside the chamber CB may be exposed to plasma for surface treatment.

The upper substrate GLS1 and the lower substrate GLS2 may be simultaneously or consecutively exposed to plasma, and in the case of continuous exposure, surface treatment conditions applied thereto may be the same or different.

In an embodiment, the upper substrate GLS1 and the lower substrate GLS2 may be simultaneously exposed to plasma inside the chamber CB.

Accordingly, the surface treatment conditions of the substrate may be the same.

The upper and lower substrates (GLS1 and GLS2) subjected to the plasma treatment may include activated surfaces on one surface or a surface.

Through the plasma surface treatment, the upper substrate GLS1 and the lower substrate GLS2 may be in a surface state in which direct bonding is possible.

For example, oxygen particles are adsorbed on the surface of the substrate to be processed according to the plasma surface treatment, and the surface can be modified to be hydrophilic and adhesion can be improved.

In an embodiment, referring to FIG. 4 together, the lower surface of the first part CW1 of the cover window and the upper surface of the second part CW2 of the cover window may be activated surfaces in which plasma surface treatment has been carried out for direct bonding.

Subsequently, FIG. 5 (c) is a step of pre-bonding the upper substrate GLS1 and the lower substrate GLS2 subjected to the surface treatment of FIG. 5 (b).

Referring to FIG. 5 (c), the activated surfaces of the upper and lower substrates (GLS1 and GLS2) may be positioned to face each other and bonded to each other.

In the preliminary bonding state of FIG. 5 (c), as shown in FIG. 5 (d), a pressing process by an external force (F) proceeds, and thus the upper substrate GLS1 and the lower substrate GLS2 become a direct bonding state.

In an embodiment, as shown in FIG. 4, the lower surface of the first part CW1 of the cover window and the upper surface of the second part CW2 of the cover window may be disposed to face each other and pre-bonded. Thereafter, a direct bonding state may be achieved through a pressing process.

Such direct bonding does not require a separate intermediate material for bonding between substrates to be bonded, and the bonded interface of substrates bonded by such direct bonding may be hardly visible.

For example, the thickness of the bonding interface formed by direct bonding is about 100 nm or less, and may be formed at a level of several nm to several tens of nm depending on the embodiment.

The thickness of the bonded interface may vary depending on the types of substrates to be bonded and surface treatment conditions.

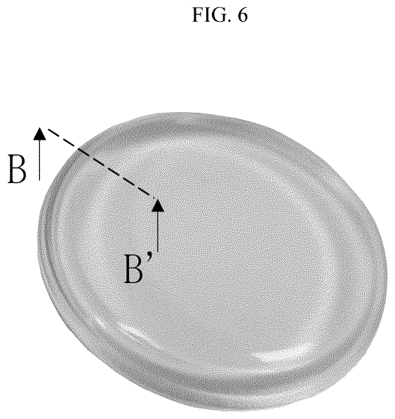

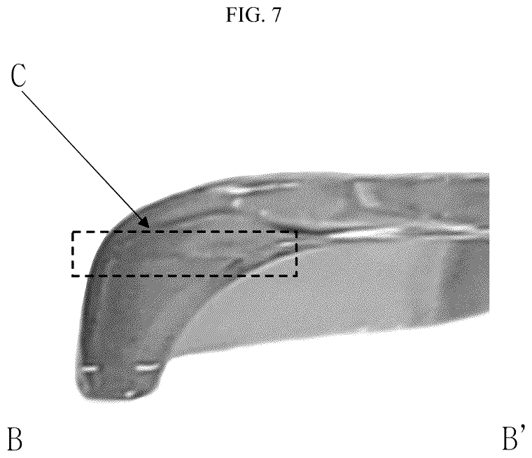

Referring to FIG. 6 and FIG. 7, a cover window connected or coupled through direct bonding according to an embodiment will be confirmed.

FIG. 6 is a photograph of a cover window according to an embodiment, and FIG. 7 is a cross-sectional photograph of the cover window taken along line B-B′ in FIG. 6. Referring to FIG. 7, it can be confirmed that the bonding interface (C) of the cover window bonded by the direct bonding process in an embodiment is not visually recognized.

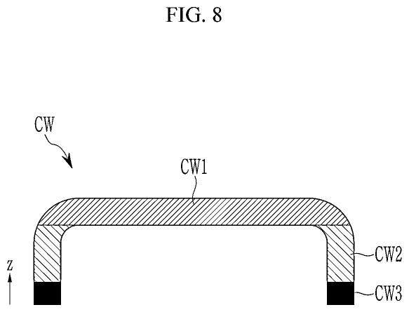

FIG. 8 is a schematic cross-sectional view of a cover window according to an embodiment.

FIG. 8 may be different from the embodiment of FIG. 3 in that the cover window may further include a third part.

For example, in the embodiment of FIG. 3, the cover window is composed of two parts, but in this embodiment, the cover window may be composed of three parts.

Each part of the cover windows is bonded by direct bonding.

Referring to FIG. 8, the cover window CW according to an embodiment may include a first part CW1, a larger second part CW2, and a third part CW3.

The first part CW1 of the cover window and the second part CW2 of the cover window are similar to the embodiment of FIG. 3.

A detailed description of the same components as in the previous embodiment will be omitted.

The third part CW3 of the cover window may include an extension protruding and extending downward from the second part CW2 of the cover window.

The third part CW3 of the cover window may have a ring-like shape and may include a curved surface.

The third part CW3 of the cover window may be formed of a material that is transparent and has high hardness.

According to embodiments, the third part CW3 of the cover window may include a black material.

In case that the third part CW3 of the cover window may include a black material, it may be used as a printing substitute material for a display device.

The second and third parts (CW2 and CW3) constituting the side part of the cover window may be formed of a material that is less hard than the first part CW1 of the cover window, but may be readily molded.

For example, the first part CW1 of the cover window may be implemented with a sapphire material, and the second and third parts (CW2 and CW3) of the cover window may be implemented with a tempered glass or ceramic material.

Portions of each cover window are directly bonded by direct bonding so that a separate adhesive material layer is not included in the middle, and the boundary is hardly visible.

Accordingly, a cover window that implements various form factors while using sapphire, which is a material of high hardness, may be provided.

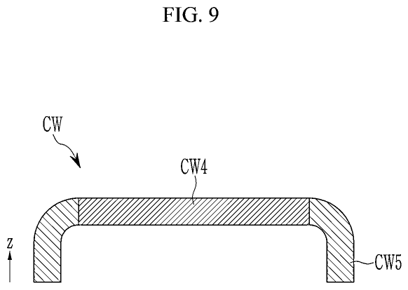

FIG. 9 is a schematic cross-sectional view of a cover window according to an embodiment.

FIG. 9 is an embodiment in which the bonding direction may be different from an embodiment of FIG. 3.

Referring to FIG. 9, the cover window CW according to an embodiment may include a first part CW4 and a second part CW5.

In the embodiment of FIG. 3, the first part CW1 of the cover window may include a flat front part and a part of the curved side part, but in this embodiment, the first part CW4 of the cover window may include only the flat front part.

Referring to FIG. 9, in an embodiment, the first part CW4 of the cover window may include a flat front part.

The first part CW4 of the cover window may be formed of a material that is transparent and has high hardness.

For example, it may include sapphire.

The second part CW5 of the cover window may include a side part extending from the front part and including a curved surface.

The second part CW5 of the cover window may extend from the first part CW4 of the cover window and may surround the first part CW4 of the cover window.

The second part CW5 of the cover window may have a ring-like shape and may include a curved surface.

The second part CW5 of the cover window may be formed of a material that is transparent and has high hardness.

For example, the second part CW5 of the cover window may be formed of tempered glass, ceramic glass, or the like within the spirit and the scope of the disclosure.

The first part CW4 of the cover window and the second part CW5 of the cover window may be formed of different materials.

The second part CW5 of the cover window may use a material having a lower hardness than that of the first part CW4 of the cover window.

Depending on the embodiment, the first part CW4 of the cover window and the second part CW5 of the cover window may be formed of the same material or a similar material.

The first part CW4 of the cover window and the second part CW5 of the cover window may be connected or coupled through direct bonding.

For example, a separate adhesive material layer is not positioned between the first part CW4 of the cover window and the second part CW5 of the cover window.

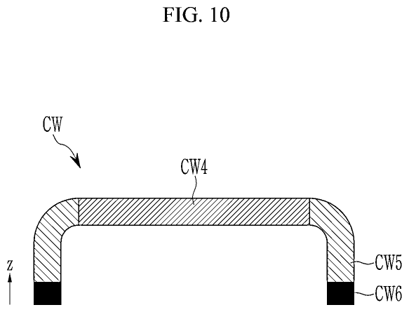

FIG. 10 is a schematic cross-sectional view of a cover window according to an embodiment.

FIG. 10 may be different from the embodiment of FIG. 9 in that the cover window may further include a third part CW6.

For example, in an embodiment of FIG. 9, the cover window is composed of two parts, but in an embodiment, the cover window may be composed of three parts.

Each part of the cover windows is made of direct bonding.

Referring to FIG. 10, the cover window CW according to an embodiment may include a first part CW4, a larger second part CW5, and a third part CW6.

The first part CW4 of the cover window and the second part CW5 of the cover window are similar to the embodiment of FIG. 9.

A detailed description of the same components as in the previous embodiment will be omitted.

The third part CW6 of the cover window may include an extension portion protruding and extending downward from the second part CW5 of the cover window.

The third part CW6 of the cover window may have a ring-like shape and may include a curved surface.

The third part CW6 of the cover window may be formed of a material that is transparent and has high hardness.

According to embodiments, the third part CW6 of the cover window may include a black material.

In case that the third part CW6 of the cover window may include a black material, it may be used as a printing substitute material for a display device.

The second and third parts (CW5 and CW6) constituting the side part of the cover window may be formed of a material that is less hard than the first part CW4 of the cover window but may be readily molded.

Portions of each cover window are directly bonded by direct bonding and do not include a separate adhesive material layer, and the boundary is hardly visible.

Accordingly, a cover window that implements various form factors while using sapphire, which is a material of high hardness, may be provided.

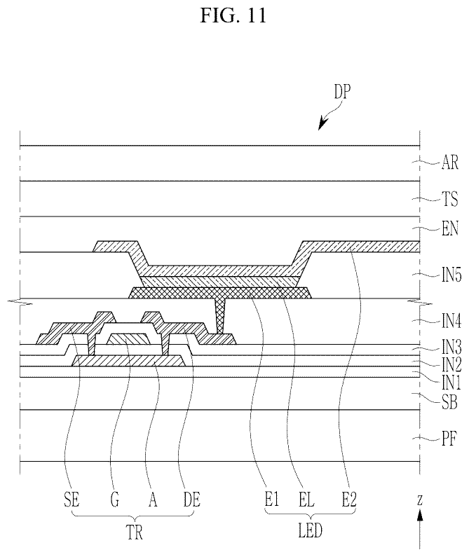

Hereinafter, a configuration of a display panel DP that may be included in a display device according to an embodiment will be described with reference to FIG. 11.

FIG. 11 is a schematic cross-sectional view of a display panel according to an embodiment.

FIG. 11 is a schematic cross-sectional view illustrating an example of a stacked structure of a display panel DP according to an embodiment.

A cross-section shown in FIG. 10 may correspond to about one pixel area.

The display panel DP may basically include a substrate SB, a transistor TR formed on the substrate SB, and a light emitting diode (LED) connected to the transistor TR.

The substrate SB may be a flexible substrate including a polymer such as polyimide, polyamide, or polyethylene terephthalate.

The substrate SB may include a barrier layer that prevents penetration of moisture, oxygen, and the like within the spirit and the scope of the disclosure.

For example, the substrate SB may include one or more polymer layers and one or more barrier layers, and the polymer layers and barrier layers may be alternately stacked each other.

The substrate SB may be a glass substrate.

An insulating layer IN1 may be positioned on the substrate SB.

The insulating layer IN1 may be referred to as a buffer layer, and upon formation of the semiconductor layer A, blocks impurities from the substrate SB to improve the characteristics of the semiconductor layer A, and flattens the surface of the substrate SB to form a semiconductor layer. The stress of layer A can be relieved.

The barrier layer and the first insulating layer IN1 may include an inorganic insulating material such as silicon nitride (SiNₓ), silicon oxide (SiOₓ), or silicon oxynitride (SiOₓN_{y}).

A semiconductor layer A of the transistor TR may be positioned on the insulating layer IN1.

The semiconductor layer A may include a first region and a second region, and a channel region between these regions.

The semiconductor layer A may include a semiconductor material such as polycrystalline silicon, oxide semiconductor, or amorphous silicon.

An insulating layer IN2 may be positioned on the semiconductor layer A.

The insulating layer IN2 may be called a gate insulating layer and may include an inorganic insulating material.

A gate conductive layer including a gate electrode G of the transistor TR may be positioned on the insulating layer IN2.

The gate conductive layer may include a metal such as molybdenum (Mo), aluminum (Al), copper (Cu), or titanium (Ti).

An insulating layer IN3 may be positioned on the gate conductive layer.

The insulating layer IN3 may be referred to as an interlayer insulating layer and may include an inorganic insulating material.

A data conductive layer including the first electrode SE and the second electrode DE of the transistor TR may be positioned on the insulating layer IN3.

The first electrode SE and the second electrode DE may be connected to the first region and second region, respectively, of the semiconductor layer A through contact holes formed in the insulating layers IN2 and IN3.

The data conductive layer may include aluminum (Al), copper (Cu), silver (Ag), molybdenum (Mo), chromium (Cr), gold (Au), platinum (Pt), palladium (Pd), tantalum (Ta), and tungsten (W), titanium (Ti), and may include a metal such as nickel (Ni).

An insulating layer IN4 may be positioned on the data conductive layer.

The insulating layer IN4 may be referred to as a planarization layer.

The insulating layer IN4 is an organic insulating material such as a general purpose polymer such as polymethyl methacrylate or polystyrene, a polymer derivative having a phenolic group, an acrylic polymer, an imide polymer, a polyimide, or a siloxane polymer.

A pixel electrode E1 may be positioned on the insulating layer IN4.

The pixel electrode E1 may be connected to the second electrode DE through a contact hole formed in the fourth insulating layer IN4.

An insulating layer IN5 may be positioned on the insulating layer IN4.

The insulating layer IN5 may be referred to as a pixel definition layer.

The insulating layer IN5 may have an opening overlapping the pixel electrode E1.

The insulating layer IN5 may include an organic insulating material.

An emission layer EL may be positioned on the pixel electrode E1, and a common electrode E2 may be positioned on the emission layer EL.

In addition to the emission layer EL, at least one of a hole injection layer, a hole transport layer, an electron transport layer, and an electron injection layer may be positioned between the pixel electrode E1 and the common electrode E2.

The pixel electrode E1, the light emitting layer EL, and the common electrode E2 may constitute a light emitting diode (LED).

The pixel electrode E1 may be an anode of the light emitting diode (LED), and the common electrode E2 may be a cathode of the light emitting diode (LED).

An encapsulation layer EN may be positioned on the common electrode E2.

The encapsulation layer EN may encapsulate the light emitting diode (LED) to prevent penetration of moisture or oxygen from the outside.

The encapsulation layer EN may be a thin film encapsulation layer including one or more inorganic layers and one or more organic layers.

For example, the encapsulation layer EN may have a triple layer structure of inorganic layer/organic layer/inorganic layer.

A touch sensor layer TS may be positioned on the encapsulation layer EN.

The touch sensor layer TS may include a touch electrode layer and an insulating layer, and the touch electrode layer may have a mesh shape.

The touch electrode layer may include a metal such as aluminum (Al), copper (Cu), titanium (Ti), molybdenum (Mo), silver (Ag), chromium (Cr), or nickel (Ni).

An anti-reflection layer AR may be positioned on the touch sensor layer TS to reduce reflection of external light.

The antireflection layer AR may include a combination of a light blocking layer and a color filter or a polarization layer.

A protective film PF for protecting the display panel DP may be positioned below the substrate SB.

The protective film PF may include a polymer such as polyethylene terephthalate, polyethylene naphthalate, or polyimide.

Although embodiments have been described in detail above, the scope of the disclosure is not limited thereto, and various modifications and improvements that would be understood by one of ordinary skill in the art using the disclosed herein and as defined in the following claims are also included in the scope of the disclosure.

What is claimed is:

1. A display device, comprising:
a display panel; and
a cover window disposed on a front side of the display panel and including a front part and a side part that surrounds the front part and is at least partially curved, wherein
the cover window includes a first part including the front part and a second part including at least a portion of the side part,
the first part and the second part being directly bonded, and
the first part having a greater hardness than the second part.

2. The display device of claim 1, wherein a thickness of a bonding interface between the first part and the second part of the cover window is less than or equal to about 100 nm.

3. The display device of claim 1, wherein the first part and the second part are directly bonded after bonding surfaces of the first and second parts are activated by plasma.

4. The display device of claim 1, wherein the side part of the cover window comprises:
a first side part protruding from the front part and having at least a portion being a substantially curved surface; and
a second side part extending downward from the first side part and having at least a portion being a substantially curved surface.

5. The display device of claim 4, wherein
the first part of the cover window includes the front part and the first side part, and
the second part of the cover window includes the second side part.

6. The display device of claim 5, wherein the first part of the cover window includes sapphire.

7. The display device of claim 5, wherein a depth from an edge of a side part of the cover window to an inner surface of a front surface is about 3 mm or more.

8. The display device of claim 4, wherein the side part of the cover window includes a third side part extending downward from the second side part and having at least a portion of a substantially curved surface.

9. The display device of claim 8, wherein
the cover window includes a third part extending from the second part,
the first part of the cover window includes the front part and the first side part, the second part of the cover window includes the second side part, and the second part of the cover window includes a third side part, and
the first part has a greater hardness than the third part.

10. The display device of claim 9, wherein the third side part of the cover window includes a black material.

11. The display device of claim 9, wherein a thickness of a bonding interface between the second part and the third part is about 100 nm or less.

12. The display device of claim 9, wherein the second part and the third part are directly bonded after bonding surfaces of the second and third parts are activated by plasma.

13. The display device of claim 9, wherein the first part of the cover window includes sapphire.

14. A display device, comprising:
a display panel; and
a cover window disposed in front of the display panel, wherein
the cover window includes a flat front part and a side part that surrounds the flat front part and is at least partially curved,
the flat front part and the side part are directly bonded, and
the flat front part has a greater hardness than the side part.

15. The display device of claim 14, wherein
the side part includes a first side part protruding and extended from the flat front part and
a second side part extending downward from the first side part.

16. The display device of claim 15, wherein the second side part includes a black material.

17. The display device of claim 15, wherein the flat front part includes sapphire.

18. The display device of claim 15, wherein a thickness of a bonding interface between the flat front part and the side part is about 100 nm or less.

19. The display device of claim 15, wherein the flat front part and the side part are directly bonded after bonding surfaces are activated by plasma.

20. The display device of claim 16, wherein
the first side part and the second side part are directly bonded, and
a bonding interface has a thickness of about 100 nm or less.
